(19) United States
(12) Patent Application Publication
(10) Pub. No.: US 2013/0306946 A1
(43) Pub. Date: Nov. 21, 2013

(54) TOUCH DISPLAY PANEL

(71) Applicants: Ting-Yu Chang, Kaohsiung County (TW); Ching-Fu Hsu, Taichung City (TW); Yu-Hua Wu, Taoyuan County (TW); Yu-Cheng Chang, Yunlin County (TW); Wen-Chun Wang, Taichung City (TW)

(72) Inventors: Ting-Yu Chang, Kaohsiung County (TW); Ching-Fu Hsu, Taichung City (TW); Yu-Hua Wu, Taoyuan County (TW); Yu-Cheng Chang, Yunlin County (TW); Wen-Chun Wang, Taichung City (TW)

(73) Assignee: WINTEK CORPORATION, Taichung City (TW)

(21) Appl. No.: 13/893,308

(22) Filed: May 13, 2013

(30) Foreign Application Priority Data
May 15, 2012 (TW) 101117246

(51) Int. Cl. H01L 27/32

(52) U.S. Cl. CPC H01L 27/323
USPC 257/40

(57) ABSTRACT

A touch display panel including a array substrate, an opposite substrate, an organic light emitting diode (OLED) structure, a plurality of conductive spacers and a sealant is provided. The OLED structure is disposed on the opposite substrate and located between the array substrate and the opposite substrate. The OLED structure includes a first electrode layer, an organic light emitting layer and a second electrode layer which are sequentially disposed. The first electrode layer is located on the opposite substrate and includes a plurality of touch sensing electrode. The second electrode layer is electrically connected to the array substrate via the conductive spacers. The sealant is sealed the OLED structure and the conductive spacers between the array substrate and the opposite substrate.

### CROSS-REFERENCE TO RELATED APPLICATION

This application claims the priority benefit of Taiwan application serial no. 101117246, filed on May 15, 2012. The entirety of the above-mentioned patent application is hereby incorporated by reference herein and made a part of this specification.

### BACKGROUND OF THE INVENTION

1. Field of the Invention

The present invention generally relates to a touch display panel, and more particularly, to a touch display panel in which organic light emitting layer is used to display.

2. Description of Related Art

In general, a conventional touch display device is a display panel externally assembled with an independent touch panel. Therefore, the conventional touch display device is comparatively thicker and heavy. In addition, the design of externally assembling the touch panel to the display panel may easily cause the degradation of transmittance. Thus, if the touch sensing function can be directly integrated in a display device, then the aforementioned problem may be effectively resolved.

### SUMMARY OF THE INVENTION

The present invention provides a touch display panel which uses an organic light emitting diode structure to display, wherein the first electrode layer of the organic light emitting diode structure includes the touch sensing electrodes. Thus, the touch display panel can have the functions of touch sensing and displaying without needing to greatly increase the thickness.

The present invention provides a touch panel including an array substrate, an opposite substrate, an organic light emitting structure, a plurality of conductive spacers and a sealant. The opposite substrate is located opposite to the array substrate. The organic light emitting diode structure is disposed on the opposite substrate and located between the array substrate and the opposite substrate. The organic light emitting diode structure includes a first electrode layer, an organic light emitting layer and a second electrode layer. The first electrode layer is disposed on the opposite substrate and includes a plurality of touch sensing electrodes. The organic light emitting layer is disposed on the first electrode layer. The second electrode layer is disposed on the organic light emitting layer. The conductive spacers are disposed between the array substrate and the organic light emitting diode structure. The second electrode layer of the organic light emitting diode structure is electrically connected to the array substrate through the conductive spacers. The sealant is disposed between the array substrate and the opposite substrate for sealing the organic light emitting diode structure and the conductive spacers between the array substrate and the opposite substrate.

According to one exemplary embodiment of the present invention, the touch sensing electrodes include a plurality of first sensing electrodes and a plurality of second sensing electrodes. The first sensing electrodes extend along a first direction, and the second sensing electrodes extend along a second direction and electrically insulated with the first sensing electrodes. The first direction is opposite to the second direction. The shape of each of the first sensing electrodes and the shape of each of the second sensing electrodes are ladder-shaped structures, and the shape of each of the first sensing electrodes and the shape of adjacent second sensing electrodes construct a rectangular structure.

According to one exemplary embodiment of the present invention, wherein the touch sensing electrodes are a plurality of first sensing series. The touch display panel further includes a plurality of second sensing series. The opposite substrate has a first surface and a second surface opposite to each other. The first sensing series and the second sensing series are located on the first surface and the second surface of the opposite substrate, respectively. The first sensing series extend along a first direction and the second sensing series extend along a second direction, wherein the first direction intersects the second direction.

According to one exemplary embodiment of the present invention, each of the first sensing series includes a first stripe electrode, and each of the second sensing series includes a second stripe electrode.

According to one exemplary embodiment of the present invention, each of the first sensing series includes a plurality of first sensing pads and a plurality of first bridge lines connecting the first sensing pads in series along the first direction, and each of the second sensing series includes a plurality of second sensing pads and a plurality of second bridge lines connecting the second sensing pads in series along the second direction.

According to one exemplary embodiment of the present invention, the touch display panel further includes a cover plate and a plurality of second sensing series. The cover plate is disposed on the opposite substrate. The second sensing series are disposed on the cover plate and located between the cover plate and the opposite substrate. The touch sensing electrodes of the first electrode layer of the organic light emitting diode structure are a plurality of first sensing series. The first sensing series extend along a first direction and the second sensing series extend along a second direction, wherein the first direction intersects the second direction.

According to one exemplary embodiment of the present invention, wherein each of the first sensing series includes a first stripe electrode, and each of the second sensing series includes a second stripe electrode.

According to one exemplary embodiment of the present invention, each of the first sensing series includes a plurality of first sensing pads and a plurality of first bridge lines connecting the first sensing pads in series along the first direction, and each of the second sensing series includes a plurality of second sensing pads and a plurality of second bridge lines connecting the second sensing pads in series along the second direction.

According to one exemplary embodiment of the present invention, the touch display panel further includes a cover plate disposed on the opposite substrate, wherein the cover plate is fixed on the opposite substrate through an adhesive layer.

According to one exemplary embodiment of the present invention, the touch display panel further includes a flexible circuit board disposed on the drive device array substrate and electrically connected to the array substrate.

In light of the above, since the first electrode layer of the organic light emitting diode structure of the present invention includes the touch sensing electrodes, an extra touch panel or an independent touch sensing electrode structure is not required to be additionally disposed, and the touch display panel can have the functions of touch sensing and displaying. Therefore, the touch display panel of the present invention can effectively reduce the thickness and the weight, and the light transmittance can also be improved. In addition, since the first electrode layer and the touch sensing electrodes which are the displaying structures are formed in the same fabricating process, the fabricating process and the manufacturing cost can be effectively reduced and the circuit layouts can be simplified.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A schematically shows a cross-sectional view of a touch display panel according to an exemplary embodiment of the present invention.

FIG. 1B illustrates a top view of the touch sensing electrodes in FIG. 1A.

FIG. 2A schematically shows a cross-sectional view of a touch display panel according to another exemplary embodiment of the present invention.

FIG. 2B illustrates a top view of portions of the first sensing series and the second sensing series in FIG. 2A according to an exemplary embodiment.

FIG. 2C illustrates a top view of portions of the first sensing series and the second sensing series in FIG. 2A according to another exemplary embodiment.

FIG. 3 schematically shows a cross-sectional view of a touch display panel according to another exemplary embodiment of the present invention.

FIG. 4 is a schematic view illustrating a distribution of a display interval and a touch sensing interval wherein the touch display panel of FIG. 1A is in two frame times.

### DESCRIPTION OF EMBODIMENTS

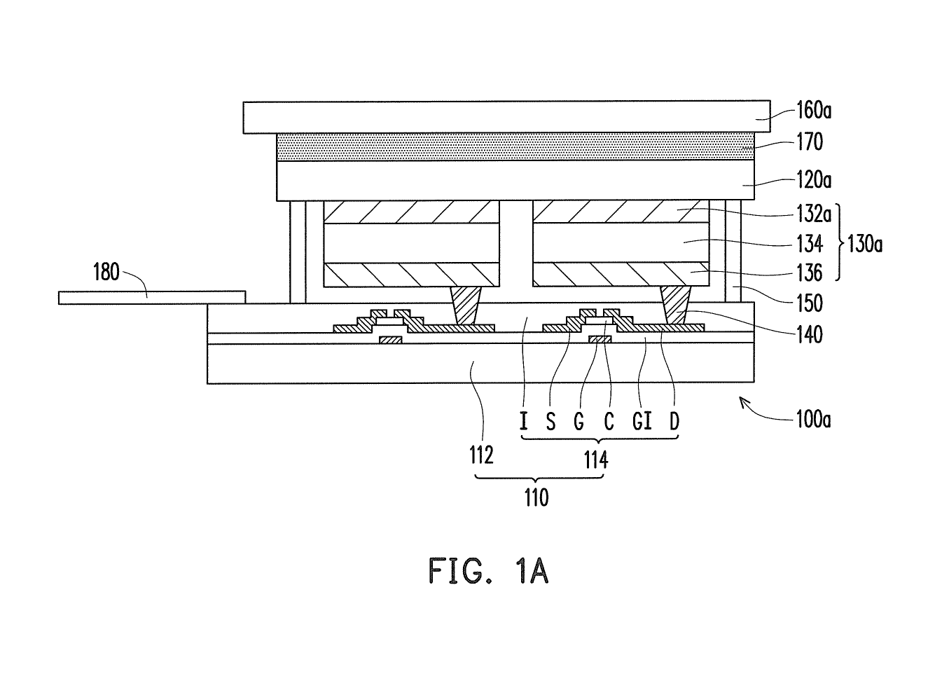

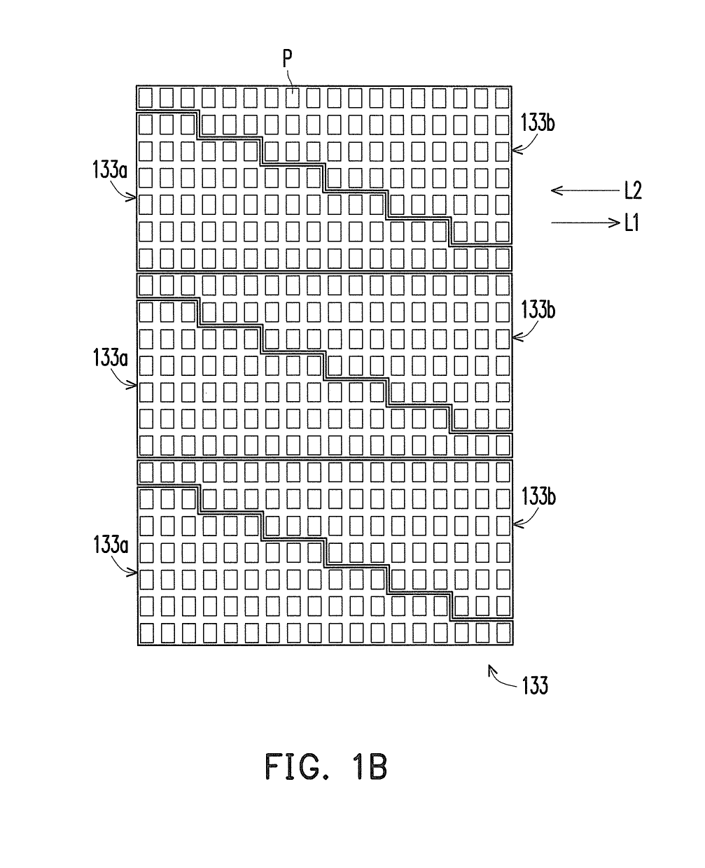

FIG. 1A schematically shows a cross-sectional view of a touch display panel according to an exemplary embodiment of the present invention. FIG. 1B illustrates a top view of the touch sensing electrodes in FIG. 1A. Referring to FIG. 1A, in the embodiment, the touch display panel 100a includes an array substrate 110, an opposite substrate 120a, an organic light emitting structure 130a, a plurality of conductive spacers 140 and a sealant 150.

In more detailed, the array substrate 110 is an active device array substrate including a substrate 112 and a plurality of active devices 114. Each of the active devices 114 includes a gate G, a gate insulating layer GI, a channel layer C, a source S, a drain D and an insulating layer I, for example. Herein the gate G is located on the substrate 112, and the gate insulating layer GI, the channel layer C, the source S/drain D and the insulating layer I are sequentially stacked on the substrate 112. In other embodiments not shown in the figures, the array substrate 110 may be a passive device array substrate, for example. In other words, the driving method of the array substrate 110 is not limited to be active or passive in the present invention. The opposite substrate 120a is located opposite to the array substrate 110, wherein the opposite substrate 120a is a transparent substrate, and the material is glass, for example.

The organic light emitting diode structure 130a is disposed on the opposite substrate 120a and located between the array substrate 110 and the opposite substrate 120a. The organic light emitting diode structure 130a includes a first electrode layer 132a, an organic light emitting layer 134 and a second electrode layer 136, wherein the first electrode layer 132a is a cathode and the second electrode layer 136 is an anode, for example. The organic light emitting layer 134 is disposed on the first electrode layer 132a, and the second electrode layer 136 is disposed on the organic light emitting layer 134. In addition, the first electrode layer 132a may be the transparent electrode, so that the light emitted by the organic light emitting layer 134 may be emitted toward the opposite substrate 120a, for example. Certainly, both the first electrode layer 132a and the second electrode layer 136 may be the transparent electrodes, so that the light emitted by the organic light emitting layer 134 may be emitted toward the array substrate 110 and the opposite substrate 120a at the same time, for example. Namely, the touch display panel 100a of the embodiment may be a single-sided display or a double-sided display, for example.

Particularly, referring to FIG. 1A and FIG. 1B together, in the fabricating process, the first electrode layer 132a of the embodiment is firstly formed on the opposite substrate 120a through a photomask, and simultaneously, in the same fabricating process, a plurality of touch sensing electrodes 133, such as capacitance touch sensing electrodes, are formed, for example. In other words, the first electrode layer 132a of the embodiment include a plurality of touch sensing electrodes 133, and the touch sensing electrodes 133 can substantially be deemed as touch sensing electrodes which are arranged in a single layer. As shown in FIG. 1B, the touch sensing electrodes 133 include a plurality of first sensing electrodes 133a and a plurality of second sensing electrodes 133b, wherein the first sensing electrodes 133a extend along a first direction L1, and the second sensing electrodes 133b extend along a second direction L2 and electrically insulated with the first sensing electrodes 133a. Herein, the first direction L1 is opposite to the second direction L2. It has to be noted that, in the embodiment, the shape of each of the first sensing electrodes 133a and the shape of each of the second sensing electrodes 133b are ladder-shaped structures, more specifically, right triangles each having a ladder-shaped hypotenuse. Moreover, each of the first sensing electrodes 133a and each of the second sensing electrodes 133b of the embodiment include a plurality of pixels P. The first sensing electrodes 133a and the second sensing electrodes 133b are separated through a photomask or by setting a separating structure, so that each of the distributed regions of first sensing electrodes 133a and each of the distributed regions of second sensing electrodes 133b which are separated include a plurality of pixels P. Certainly, in other embodiments not shown in the figures, the first sensing electrodes 133a and the second sensing electrodes 133b can also be other shapes of single-layered sensing electrodes, such as single-layered sensing electrodes including a plurality of strip sensing electrodes, array single-layered sensing electrodes including a plurality of rectangular sensing electrodes, or single-layered sensing electrodes including any other polygonal sensing electrodes, which still falls within the technical schemes adopted by the present invention without departing from the scope of the present invention. Then, after the first electrode layer 132a is formed, the organic light emitting layer 134 and the second electrode layer 136 are sequentially Ruined, in order to form the organic light emitting diode structure 130a.

The conductive spacers 140 are disposed between the array substrate 110 and the organic light emitting diode structure 130a, wherein the second electrode layer 136 of the organic light emitting diode structure 130a is electrically connected to the array substrate 110 via the conductive spacers 140. More specifically, the second electrode layer 136 of the organic light emitting diode structure 130a is electrically connected to the drain D of the active device 114 of the array substrate 110 through the conductive spacers 140. The sealant 150 is disposed between the array substrate 110 and the opposite substrate 120a, so as to enable the organic light emitting diode structure 130a and the conductive spacers 140 to be lain between the array substrate 110 and the opposite substrate 120a. The sealant is ultraviolet (UV) light hardening resin, thermosetting resin, frits or the like.

In addition, the touch display panel 100a further includes a cover plate 160a and a flexible circuit board 180. The cover plate 160a is disposed on the opposite substrate 120a, wherein the cover plate 160a is fixed on the opposite substrate 120a through an adhesive layer 170 for protecting the opposite substrate 120a. Herein, the material of the cover plate 160 is glass or plastic, and the material of the adhesive layer 170 is an optical adhesive, for example. The flexible circuit board 180 is disposed on the array substrate 110 and electrically connected to the array substrate 110, wherein the touch display panel 100a is electrically connected to an external circuit (not shown) through the flexible circuit board 180.

In the embodiment, the organic light emitting diode structure 130a is used for display function in the touch display panel 100a, and the first electrode layer 132a of the organic light emitting diode structure 130a can provide the touch sensing function, wherein the touch sensing electrodes 133 are built in the first electrode layer 132a of the organic light emitting diode structure 130a. As a result, without needing an extra touch panel or an independent touch sensing electrode structure to be additionally disposed, the touch display panel 100a of the present embodiment can have the functions of touch sensing and displaying. Therefore, the touch display panel 100a can effectively reduce the thickness and the weight, and the light transmittance can also be enhanced. In addition, since the first electrode layer 132a and the touch sensing electrodes 133 are formed in the same fabricating process, the fabricating process and the manufacturing cost can be effectively reduced and the circuit layouts can be simplified. Moreover, since the organic light emitting diode structure 130a is disposed on the opposite substrate 120a, the first electrode layer 132a and the touch sensing electrodes 133 are comparatively closer to the touch sensing interface, and thus the sensitivity of touch sensing can be effectively increased. In addition, the first electrode layer 132a and the touch sensing electrodes 133 are comparatively farther from the array substrate 110, and thus the noise problem of touch sensing signals can be effectively reduced.

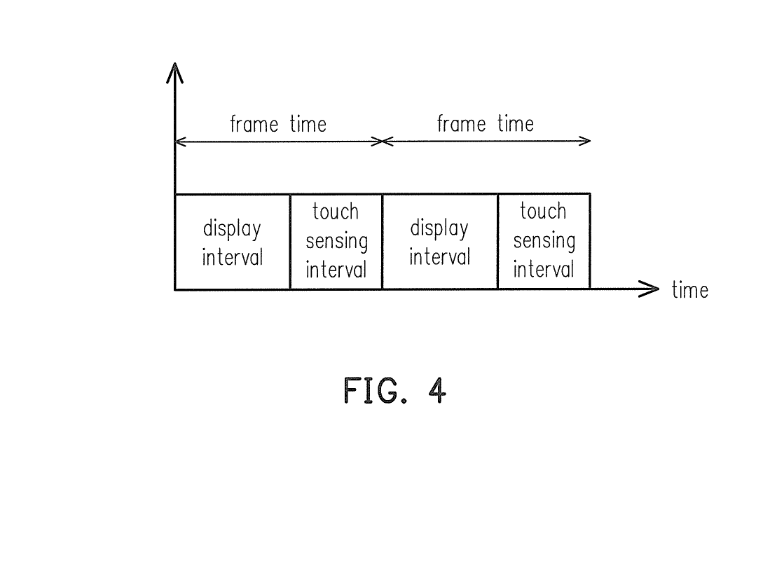

It should be noted that, referring to FIG. 4, since the first electrode layer 132a acts as display structure and touch sensing structure both, during the operating process of the touch display panel 100a, display timing and touch sensing timing are needed to be separated. That is, the frame time of each of the display image is divided into a display interval and a touch sensing interval. For instance, during the display interval, the first electrode layer 132a of the touch display panel 100a is 0V or negative voltage, and the second electrode layer 136 is the voltage of corresponding image data. At this time, during the touch sensing interval, the first electrode layer 132a is connected to the touch sensing signal, and the second electrode layer 136 is 0V.

The following exemplary embodiments of the present invention are illustrated with accompanied drawings, wherein the same or similar parts are denoted with same reference numerals, and repetitive descriptions are omitted. For a detailed description of this section, reference can be found in the first embodiment of the invention, therefore no further description is contained herein.

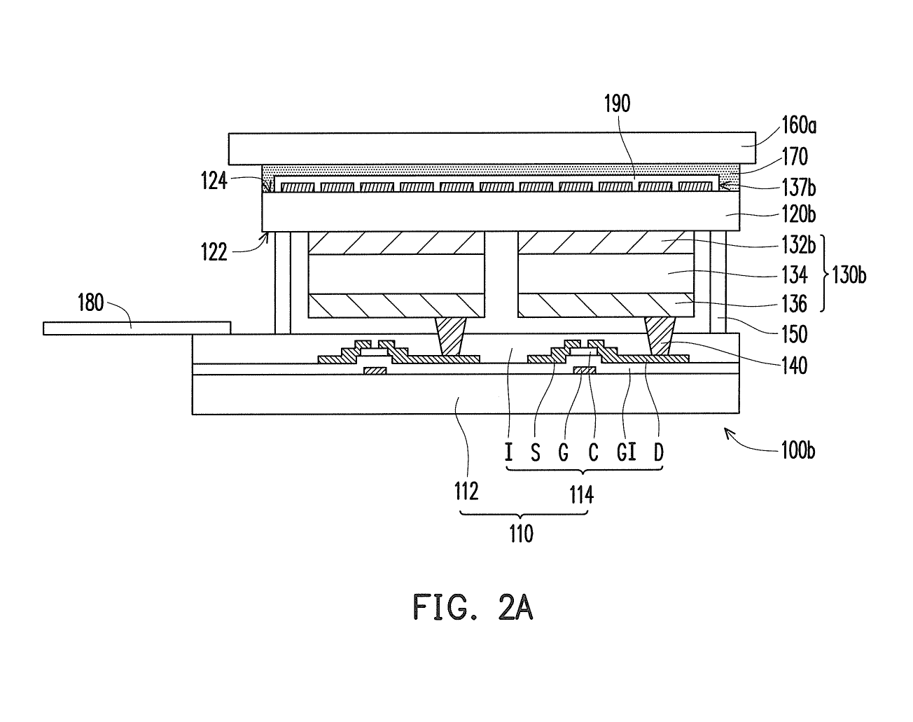

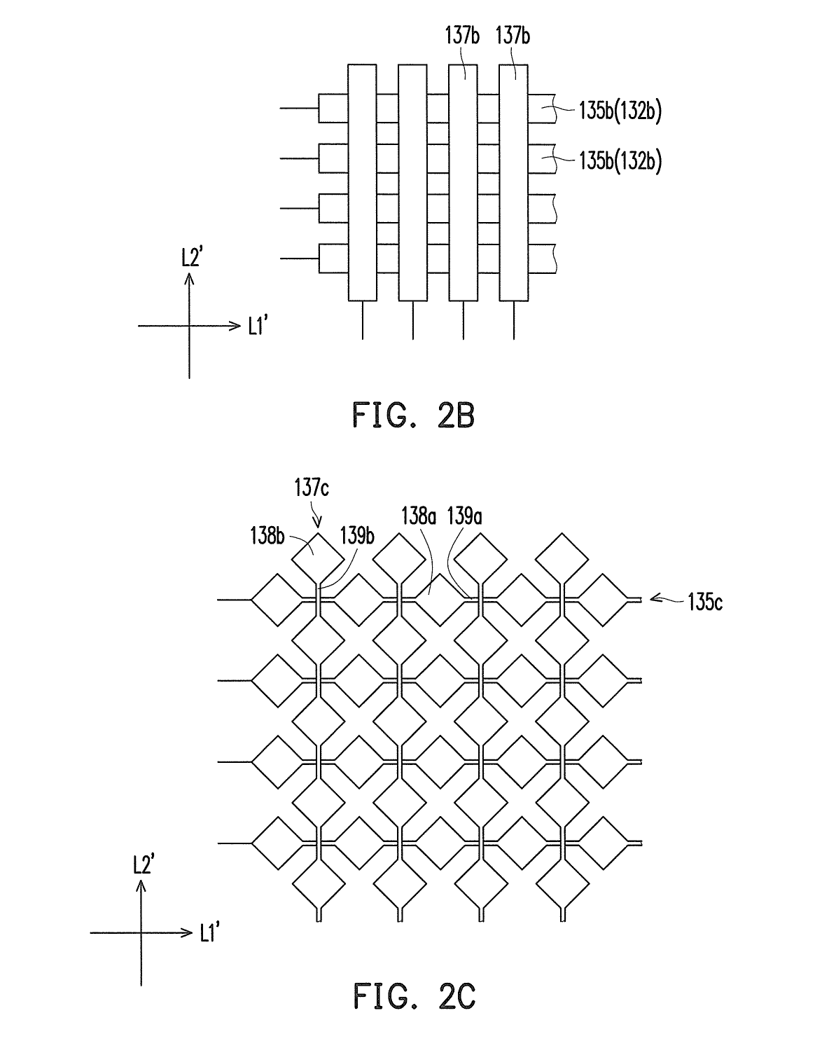

FIG. 2A schematically shows a cross-sectional view of a touch display panel according to another exemplary embodiment of the present invention. FIG. 2B illustrates a top view of portions of the first sensing series and the second sensing series in FIG. 2A according to an exemplary embodiment. For the sake of description convenience, the opposite substrate located between the first sensing series and the second sensing series is omitted in FIG. 2B. Referring to FIG. 2A and FIG. 2B, the touch display panel of the embodiment 100b is similar to the touch display panel 100a of FIG. 1A, and the difference is that: the touch sensing electrodes of the first electrode layer 132b of the organic light emitting diode structure 130b of the embodiment are a plurality of first sensing series 135b, and the touch display panel 100b further includes a plurality of second sensing series 137b.

In specifically, the opposite substrate 120b has a first surface 122 and a second surface 124 opposite to the first surface 122. The first sensing series 135b and the second sensing series 137b are located on the first surface 122 and the second surface 124 of the opposite substrate 120b, respectively. Herein, the first sensing series 135b extend along a first direction LP and the second sensing series 137b extend along a second direction L2′, wherein the first direction LF intersects the second direction L2′. As shown in FIG. 2B, each of the first sensing series 135b includes a first stripe electrode, and each of the second sensing series 137b includes a second stripe electrode. It should be noted that the first sensing series 135b are used as the scan lines in display mode, and are also used as the driving lines in touch sensing mode, and the second sensing series 137b are used as sensing lines in touch sensing mode. Additionally, the touch display panel 100b further includes a protecting layer 190 which covers the second sensing series 137b, and the cover plate 160a is fixed onto the opposite substrate 120b through the adhesive layer 170. Herein, the adhesive layer 170 encapsulates the protecting layer 190.

It has to be mentioned that the structure of the first sensing series 135b and the second sensing series 137b is not limited in the present invention, although the first sensing series 135b are specified to be the first stripe electrodes and the second sensing series 137b are specified to be the second stripe electrodes in the embodiment. FIG. 2C illustrates a top view of portions of the first sensing series and the second sensing series in FIG. 2A according to another exemplary embodiment. For the sake of description convenience, the opposite substrate located between the first sensing series and the second sensing series is omitted in FIG. 2C. Referring to FIG. 2C, each of the first sensing series 135c includes a plurality of first sensing pads 138a and a plurality of first bridge lines 139a connecting the first sensing pads 138a in series along the first direction L1′, and each of the second sensing series 137c includes a plurality of second sensing pads 138b and a plurality of second bridge lines 139b connecting the second sensing pads 138b in series along the second direction L2′. The aforementioned structure in the embodiment still belongs to a technical means adoptable in the present invention and falls within the protection scope of the present invention.

In the touch display panel 100b of the embodiment, the first sensing series 135b (or 135c) and the second sensing series 137b (or 137c) are located on the first surface 122 and the second surface 124 of the opposite substrate 120b, respectively. It means that only two substrates are necessary, i.e., the array substrate 110 and the opposite substrate 120b, and thus components for display function and components for touch sensing function are integrated. Therefore, under the condition of without significantly increasing the thickness of the touch display panel 100b, the touch display panel 100b of the present embodiment can have both touch sensing function and display function.

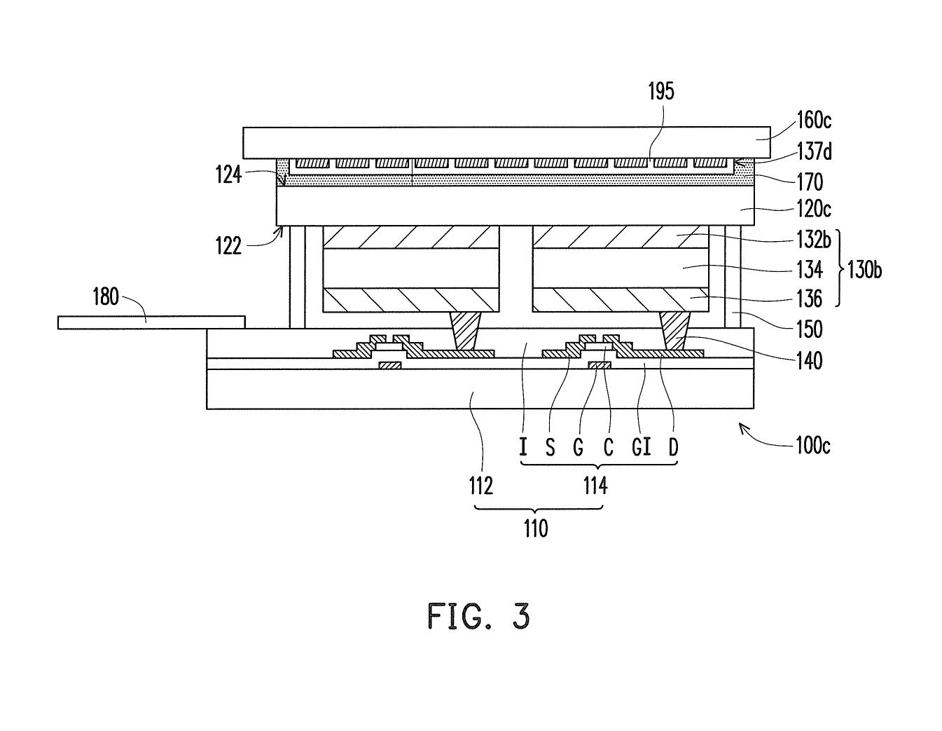

FIG. 3 schematically shows a cross-sectional view of a touch display panel according to another exemplary embodiment of the present invention. Referring to FIG. 3, the touch display panel 100c of the embodiment is similar to the touch display panel 100b of FIG. 2, and the difference is that: the disposing locations of the second sensing series 137d are different. Specifically, the second sensing series 137d of the embodiment are disposed on the cover plate 160c and located between the cover plate 160c and the opposite substrate 120c. Additionally, the touch display panel 100c further includes a protecting layer 195 which covers the second sensing series 137d, and the cover plate 160c is fixed onto the opposite substrate 120c through the adhesive layer 170. The adhesive layer 170 encapsulates the protecting layer 195. Herein, the second sensing series 137d are used as sensing lines in touch sensing mode, and the first sensing series 135b of the first electrode layer 132b (referring to FIG. 2B) are not only used as the power source in display mode, but also be used as the driving lines in touch sensing mode.

In light of the foregoing, since the touch display panel of the present invention uses the organic light emitting diode structure to display and the first electrode layer of the organic light emitting diode structure can further used as touch sensing electrodes, an extra touch panel or an independent touch sensing electrode structure is not required to be additionally disposed, and the touch display panel of the present invention can have the functions of touch sensing and displaying. Therefore, the touch display panel of the present invention can effectively reduce the thickness and the weight, and the light transmittance can also be improved. In addition, since the first electrode layer and the touch sensing electrodes which are the displaying structures are formed in the same fabricating process, the fabricating process and the manufacturing cost can be effectively reduced and the circuit layouts can be simplified. Furthermore, the thickness of the touch display panel of the present invention is comparatively thinner, and thus can comply with the current trend of miniaturizing devices.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A touch display panel, comprising:
an array substrate;
an opposite substrate located opposite to the array substrate;
an organic light emitting diode structure disposed on the opposite substrate and located between the array substrate and the opposite substrate, wherein the organic light emitting diode structure comprises:
a first electrode layer disposed on the opposite substrate and comprising a plurality of touch sensing electrodes;
an organic light emitting layer disposed on the first electrode layer; and
a second electrode layer disposed on the organic light emitting layer;
a plurality of conductive spacers disposed between the array substrate and the organic light emitting diode structure, wherein the second electrode layer of the organic light emitting diode structure is electrically connected to the array substrate via the conductive spacers; and
a sealant disposed between the array substrate and the opposite substrate for sealing the organic light emitting diode structure and the conductive spacers between the drive array substrate and the opposite substrate.

2. The touch display panel as claimed in claim 1, wherein the touch sensing electrodes comprise a plurality of first sensing electrodes and a plurality of second sensing electrodes, the first sensing electrodes extend along a first direction, the second sensing electrodes extend along a second direction and are electrically insulated with the first sensing electrodes, the first direction is opposite to the second direction, a shape of each of the first sensing electrodes and a shape of each of the second sensing electrodes are ladder-shaped structures, and a shape of each of the first sensing electrodes and a shape of adjacent second sensing electrodes construct a rectangular structure.

3. The touch display panel as claimed in claim 1, wherein the touch sensing electrodes comprise a plurality of first sensing series, the touch display panel further comprises a plurality of second sensing series, the opposite substrate has a first surface and a second surface opposite to the first surface, the first sensing series and the second sensing series are respectively located in the first surface and the second surface of the opposite substrate, the first sensing series extend along a first direction, the second sensing series extend along a second direction, and the first direction intersects the second direction.

4. The touch display panel as claimed in claim 3, wherein each of the first sensing series comprises a first stripe electrode, and each of the second sensing series comprises a second stripe electrode.

5. The touch display panel as claimed in claim 3, wherein each of the first sensing series comprises a plurality of first sensing pads and a plurality of first bridge lines connecting the first sensing pads in series along the first direction, each of the second sensing series comprises a plurality of second sensing pads and a plurality of second bridge lines connecting the second sensing pads in series along the second direction.

6. The touch display panel as claimed in claim 1, further comprising:
a cover plate disposed on the opposite substrate; and
a plurality of second sensing series disposed on the cover plate and located between the cover plate and the opposite substrate, wherein the touch sensing electrodes of the first electrode layer of the organic light emitting diode structure are a plurality of first sensing series, the first sensing series extend along a first direction, the second sensing series extend along a second direction, and the first direction intersects the second direction.

7. The touch display panel as claimed in claim 6, wherein each of the first sensing series comprises a first stripe electrode, and each of the second sensing series comprises a second stripe electrode.

8. The touch display panel as claimed in claim 6, wherein each of the first sensing series comprises a plurality of first sensing pads and a plurality of first bridge lines connecting the first sensing pads in series along the first direction, each of the second sensing series comprises a plurality of second sensing pads and a plurality of second bridge lines connecting the second sensing pads in series along the second direction.

9. The touch display panel as claimed in claim 1, further comprising:
a cover plate disposed on the opposite substrate, wherein the cover plate is fixed on the opposite substrate through an adhesive layer.

10. The touch display panel as claimed in claim 1, further comprising:
a flexible circuit board disposed on the array substrate and electrically connected to the array substrate.

11. A touch display panel, comprising:
an array substrate;
an opposite substrate located opposite to the array substrate;
an organic light emitting diode structure disposed on the opposite substrate and located between the array substrate and the opposite substrate, wherein the organic light emitting diode structure comprises a plurality of touch sensing electrodes;
a plurality of conductive spacers disposed between the array substrate and the organic light emitting diode structure, wherein the organic light emitting diode structure is electrically connected to the array substrate via the conductive spacers; and
a sealant disposed between the array substrate and the opposite substrate.
